(19) United States
(12) Patent Application Publication
(10) Pub. No.: US 2005/0040032 A1
(43) Pub. Date: Feb. 24, 2005

(54) Stamper forming method

(76) Inventor: Yuan-Chang Lai, Taipei (TW)

Correspondence Address: BIRCH STEWART KOLASCH & BIRCH, PO BOX 747, FALLS CHURCH, VA, 22040-0747, US

(21) Appl. No.: 10/642,287

(22) Filed: Aug. 18, 2003

(51) Int. Cl. C23C 14/00

(52) U.S. Cl. 204/192.15

(57) ABSTRACT

A stamper forming method includes following steps of forming a photoresist layer on a substrate, forming a patterned semi-blocked layer on the photoresist layer, exposing the photoresist layer with a light beam, developing the photoresist layer, and sputtering towards the photoresist layer to form a metal layer. In this case, the semi-blocked layer decays the intensity of the light beam, and partially blocks the light beam.

### BACKGROUND OF THE INVENTION

1. Field of Invention

The invention relates to a stamper forming method and, in particular, to a stamper forming method for manufacturing digital audio/video (AV) optical disks.

2. Related Art

During the optical disk production processes, the original digital data or signals have to be converted into laser embossing signals. After completing the embossing and electroplating processes in a clean room, a master for mass production is then produced. The master is used to make a stamper for subsequent production processes.

As shown in FIG. 1A, a conventional DVD-RW stamper 1 is formed with a plurality of grooves of the same depth, H1 (about 25 nm to 30 nm), in a readable embossed area (Area A) and an unreadable embossed area (Area B). To make optical disks compatible with CD-ROM drives and to allow a normal DVD-ROM to read optical disks with the DVD-RW format, signals in the readable embossed area (Area A) are partially modified in DVD-RW Ver 1.1. More explicitly, the groove depth of the readable embossed area (Area A) is increased to 100 nm, as a stamper 1′ shown in FIG. 1B, for enhancing the signal reading mode.

In the current manufacturing processes, leaser beams of different strengths are used to directly expose the positive photoresist formed on the stamper 1′. For example, when etching the positive photoresist on the readable embossed area (Area A), a laser beam of higher strength is used to expose the positive photoresist formed on the Area A so as to obtain a desired groove depth of 100 nm. When etching the positive photoresist on the unreadable embossed area (Area B), a laser beam of lower strength is used to expose the positive photoresist formed on the Area B so as to obtain another desired groove depth of about 25 nm to 30 nm.

In the above-mentioned processes, laser beams of different strengths are generated from the same laser source. By adjusting the laser source, the laser beams of different strengths are generated. Since the laser source is adjusted during this process, the intensity of the laser beams are unstable resulting in the poor uniformity of the groove depths. In particular, the mentioned problem always occurs when the laser source is adjusted to generate the laser beam of lower strength for exposing the positive photoresist formed oh the Area B.

Therefore, it is an important subjective to provide a stamper forming method, which can prevent the poor uniformity of the groove depths when adjusting the laser source.

### SUMMARY OF THE INVENTION

In view of the foregoing subjective, it is an objective of the invention to provide a stamper forming method, which can form different groove depths with a laser beam of the same intensity.

To achieve the above objective, the invention provides a stamper forming method including the following steps: forming a photoresist layer on a substrate, forming a patterned semi-blocked layer on the photoresist layer, exposing the photoresist layer with a light beam, developing the photoresist layer, and sputtering towards the photoresist layer to form a metal layer. In the invention, the semi-blocked layer is used to decay the intensity of the light beam so as to partially block the light beam.

Since the stamper forming method of the invention provides a semi-blocked layer on the photoresist layer for decaying the intensity of the light beam, the light beam with a single strength can be used to expose the photoresist layer so as to form the different groove depths (as the mentioned groove depths H1 and H2). Therefore, the poor uniformity of the groove depths when adjusting the laser source according to the conventional method is prevented.

### BRIEF DESCRIPTION OF THE DRAWINGS

The invention will become more fully understood from the detailed description given herein below illustrations only, and thus is not limitative of the present invention, and wherein:

FIG. 1A is a schematic view showing a part of a DVD-R stamper;

FIG. 1B is a schematic view showing a part of a DVD-R Ver 1.1 stamper;

FIG. 2 is a block diagram showing a stamper forming method according to an embodiment of the invention; and

FIGS. 3A to 3F are schematic views showing a DVD-RW Ver 1.1 stamper manufactured by the stamper forming method according to an embodiment of the invention.

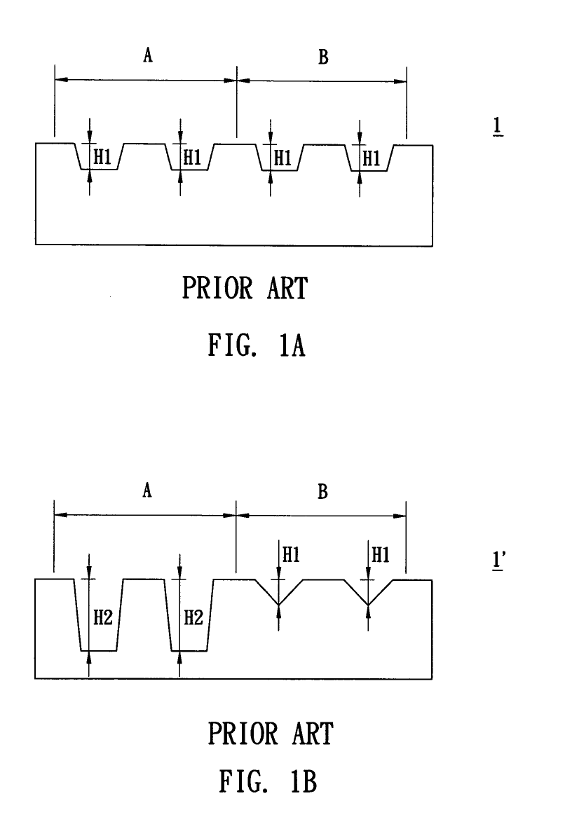

### DETAILED DESCRIPTION OF THE INVENTION

The present invention will be apparent from the following detailed description, which proceeds with reference to the accompanying drawings, wherein the same references relate to the same elements.

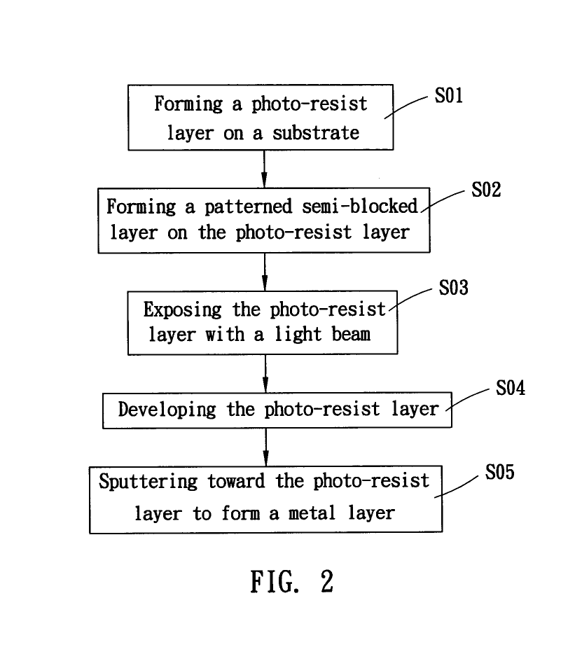

With reference to FIG. 2, the stamper forming method according to a preferred embodiment of the invention includes the following steps. First, a photoresist layer is formed on a substrate (S01). A patterned semi-blocked layer is then formed on the photoresist layer (S02). A light beam is used to expose the photoresist layer (S03), and the photoresist is then developed (S04). Finally, a metal target is sputtered toward the photoresist layer to form a metal layer (S05). It should be noted that the stamper forming method is used to manufacturing an optical disc stamper. In particular, it is an optical disk stamper for making digital versatile discs (DVD's).

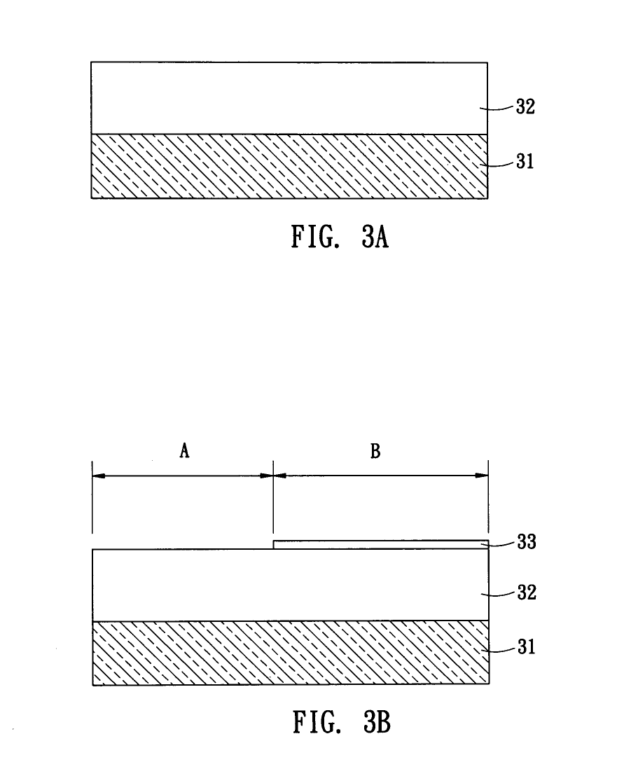

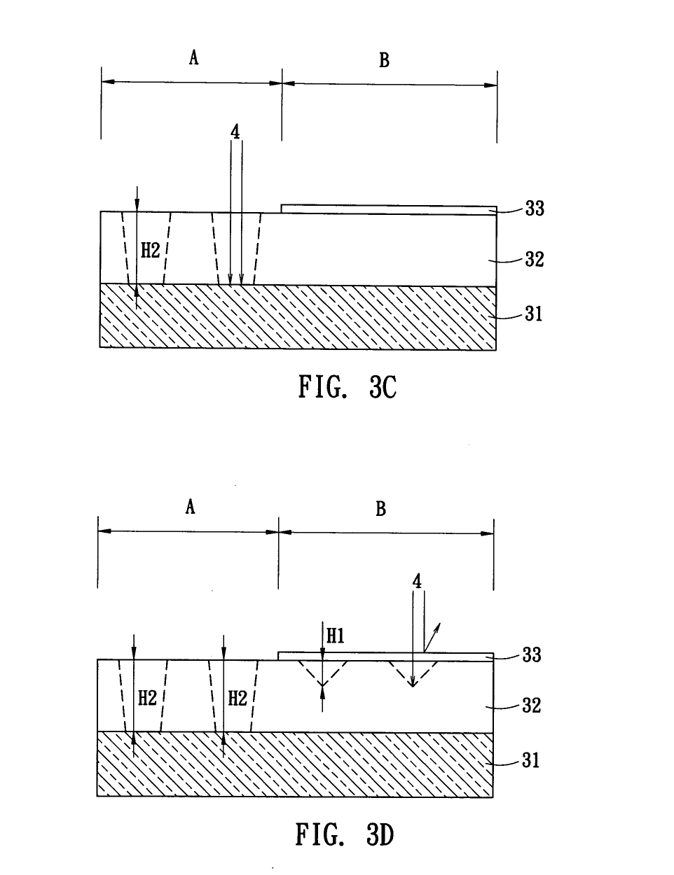

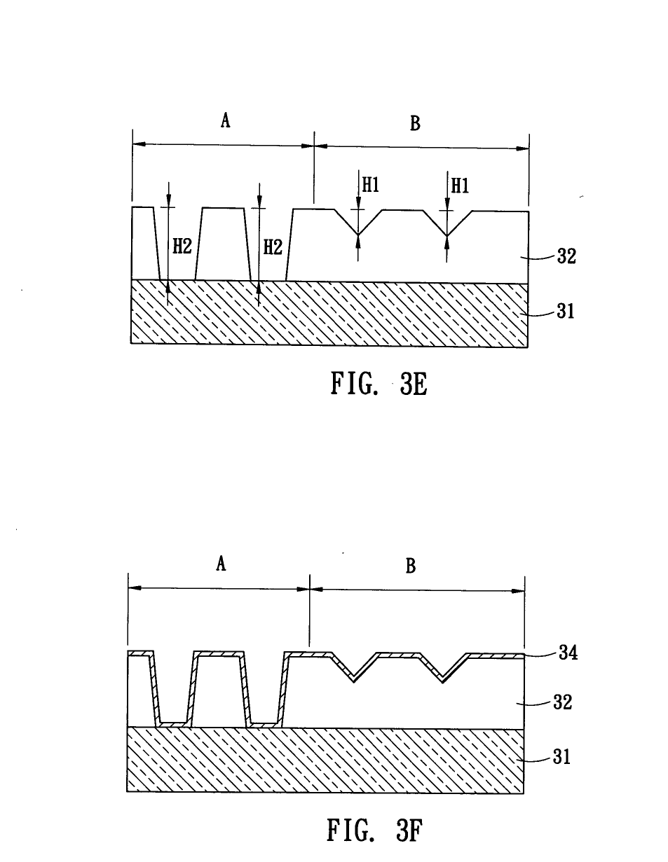

To make the invention clearer, the stamper forming method according to a preferred embodiment will be described herein below with reference to FIG. 3A to FIG. 3F.

Referring to FIG. 3A, a photoresist layer 32 is coated on a substrate 31 in step S01. The substrate 31 is a glass substrate. In the current embodiment, before coating the photoresist layer 32, the surface of the substrate 31 is cleaned with a detergent. The surface is then coated with a primer, thereby enhancing the binding between the substrate 31 and the photoresist layer 32.

In step S02, a patterned semi-blocked layer 33 is formed on the photoresist layer 32 (as shown in FIG. 3B). In the current embodiment, the semi-blocked layer 22 is formed on the entire photoresist layer 32, and is then patterned. Thus, the patterned semi-blocked layer 33 covers the unreadable embossed area (Area B). The semi-blocked layer 33 can be a semi-reflecting layer, which consists of silver, so as to reflect a part of the light beam and to allow the other part of the light beam passing therethrough. It should be noted that the stamper further includes a data area, which the patterned semi-blocked layer 33 covers.

In step S03, a light beam 4 is used to expose the photoresist layer 32, wherein the semi-blocked layer 33 can decay the intensity of the light beam 4 and partially block the light beam 4 (as shown in FIG. 3C and FIG. 3D). In this step, the digital data on an original work tape are converted into high-frequency signals by a mastering interface system (MIS) and output to a reader. Afterwards, a beam emitter (not shown) is driven to emit a light beam on the substrate 31 coated with the photoresist layer 32 to perform a data transferring process. When the light spot formed from the light beam 4 is moved on the photoresist layer 32 in the readable embossed area (Area A), the photoresist layer 32 is directly exposed and can be exposed deeper such as the previously mentioned groove depth H2 (100 nm). When the light spot is moved on the photoresist layer 32 in the unreadable embossed area (Area B), the light beam 4 is blocked by the semi-blocked layer 33 and the intensity of it is decayed. For example, if the semi-blocked layer 33 is a semi-reflecting layer, a part of the light beam 4 will be reflected. Accordingly, the other part of the light beam 4 can penetrate through the semi-blocked layer 33. The un-blocked light beam 4 can not expose the photoresist layer 32 as deep as the previously mentioned groove depth H2. Thus, a groove depth Hi (about 25 nm to 30 nm) is obtained.

In the current embodiment, the light beam 4 can be an ultraviolet (UV) laser beam. The light spot formed from the UV laser beam can meet the standards used in recording a high-density DVD. Furthermore, the evenness of the disk must be tested before the exposing process so as to ensure the product yield. The light beam 4 of the embodiment is emitted from the same light source and has a steady intensity.

In step S04, a development solution washes away the exposed photoresist 32, as shown in FIG. 3E. In the present embodiment, the development solution is an alkaline solution (e.g., NaOH and KOH). It should be noted that the semi-blocked layer 33 can be stripped in the step S04, or before photoresist layer 32 is developed.

Finally, in step S07, a metal target is sputtered toward the photoresist layer 32 to form a metal layer 34 (see FIG. 3F). In this case, the sputtered metal layer 34 is formed on the exposed and developed uneven parts of the stamper. The metal layer 34 functions as an electrode for the subsequent electroplating processes. In this embodiment, the metal layer 34 is made of an Ni/V alloy.

In summary, since the stamper forming method of the invention employs a semi-blocked layer for decaying the intensity of the light beam, the light beam with a single strength can be used to expose the photoresist layer so as to form the different groove depths (as the mentioned groove depths H1 and H2). Thus, the poor uniformity of the groove depths when adjusting the laser source is prevented. The production yield is than improved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A stamper forming method for manufacturing a stamper, comprising:
forming a photoresist layer on a substrate;
forming a patterned semi-blocked layer on the photoresist layer;
exposing the photoresist layer with a light beam, wherein the semi-blocked layer decays the intensity of the light beam so as to partially block the light beam;
developing the photoresist layer; and
sputtering towards the photoresist layer to form a metal layer.

2. The method of claim 1, wherein the stamper comprises a readable embossed area and an unreadable embossed area, and the semi-blocked layer is formed on the readable embossed area and is not formed on the readable embossed area.

3. The method of claim 2, wherein the stamper further comprises a data area, and the semi-blocked layer is further formed on the data area.

4. The method of claim 1, further comprising:
stripping the semi-blocked layer before developing the photoresist layer.

5. The method of claim 1, wherein the-semi-blocked layer is a semi-reflecting layer.

6. The method of claim 5, wherein the semi-blocked consists of silver.

7. The method of claim 1, wherein the substrate is a glass substrate.

8. The method of claim 1, wherein the light beam directly exposes a part of the photoresist layer, and the semi-blocked layer does not cover the part of the photoresist.

9. The method of claim 1, wherein the light beam partially passes through the semi-blocked layer to expose a part of the photoresist layer located underneath the semi-blocked layer.

10. The method of claim 1, wherein the metal layer is made of a NiV alloy.

11. The method of claim 1, wherein the stamper is an optical disc stamper.
